(19) United States
(12) Patent Application Publication
(10) Pub. No.: US 2009/0290305 A1
(43) Pub. Date: Nov. 26, 2009

(54) ENTRAINMENT HEATSINK USING ENGINE BLEED AIR

(76) Inventors: Wei Yang, Minnetonka, MN (US); Alex Gu, Plymouth, MN (US)

Correspondence Address: HONEYWELL INTERNATIONAL INC.;PATENT SERVICES, 101 COLUMBIA ROAD, P O BOX 2245, MORRISTOWN, NJ, 07962-2245, US

(21) Appl. No.: 12/186,053

(22) Filed: Aug. 5, 2008

Related U.S. Application Data
(60) Provisional application No. 61/054,696, filed on May 20, 2008.

(51) Int. Cl. H05K 7/20

(52) U.S. Cl. 361/690; 165/80.3; 361/691; 361/692; 361/701; 361/703

(57) ABSTRACT

An entrainment heatsink system and method using distributed micro jets. Such a system and/or method utilize a pressurized primary flow through arrays of micro nozzles to entrain a much larger secondary flow to carry heat away from the heatsink. The bleed air from an aircraft engine represents an ideal pressurized air source for the primary flow with respect to such a heatsink. As such, the needed high-pressure primary flow is very small and can be delivered via thin air hoses, which has the flexibility to reach constraint spaces. In addition to the entrainment effect, the distributed micro jets also induce a high level of turbulence in the heatsink, significantly enhancing heat transfer and cooling performance.

### CROSS-REFERENCE TO PROVISIONAL PATENT APPLICATION

This patent application claims priority to U.S. Provisional Patent Application Ser. No. 61/054,696, entitled “Entrainment Heatsink Using Engine Bleed Air,” which was filed on May 20, 2008, the disclosure of which is incorporated herein by reference in its entirety.

### TECHNICAL FIELD

Embodiments are generally related to heatsink devices and systems thereof. Embodiments are also related to air-cooling technology. Embodiments are specifically related to techniques for cooling integrated circuit chips and components thereof. Embodiments are additionally related to heatsink components utilized in avionics.

### BACKGROUND OF THE INVENTION

Electronic cooling has been a major impediment for system size reduction and often dictates external dimensions and form factors for computers and other equipments. Electronic systems are generally provided with a large number of heat-generating components such as, for example, microprocessors, power amplifiers, radio frequency (RF) devices and high-power lasers. The functional integrity of such electronic components can be maintained by keeping the temperature of these components below a predetermined value.

A heat exchanger, for example, can be utilized for efficient heat transfer from heat-generating components to ambient air. Conventional heat exchangers rely on an external air-moving component such as, for example, a blower or a fan, to provide airflow for convective heat transfer. For example, the heat exchanger for a CPU (Central Processing Unit) cooling in a desktop computer includes the use of a finned heatsink and a fan. However, such heat exchangers are generally not adequate for space-constraint applications such as avionic systems in which printed board assemblies (PBA) are often placed in proximity and would only allow low-profile heatsink structures/devices to be mounted onboard and direct fan attachment typically is not feasible.

Aircraft engine bleed air has been utilized for various operational needs such as cabin pressurization, air conditioning, ventilation, and cooling electronic chassis. However, the current depressurized engine bleed air available for avionics cooling requires the use of high-flow duct work, rendering it difficult to reach space constraint areas, such as those found in typical avionics applications.

Based on the foregoing it is believed that a need exists for an improved heatsink that can be adapted for enhanced performance in applications found in avionic systems.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved heatsink.

It is a further aspect of the present invention to provide an entrainment heatsink.

It is yet a further aspect of the present invention to provide for the use of pressurized engine bleed air as the primary flow for an entrainment heatsink.

The aforementioned aspects and other objectives and advantages can now be achieved as described herein. An entrainment heatsink system and method utilizing distributed micro jets is disclosed. Such a system and/or method employ a pressurized primary flow through arrays of micro nozzles to entrain a much larger secondary flow to carry heat away from the heatsink. The pressurized bleed air from an aircraft engine represents an ideal pressurized air source for the primary flow for such a heatsink. As such, the needed high-pressure primary flow is very small and can be delivered via thin tubing, which has the flexibility to reach constraint spaces. In addition to the entrainment effect, the distributed micro jets also induce a high level of turbulence in the heatsink, significantly enhancing heat transfer and cooling performance.

The dense array of micro nozzles and the air channels are incorporated onto the fins of the entrainment heatsink to facilitate the micro jet entrainment and can be fabricated by utilizing various micro fabrication technologies. The heat exchanger disclosed herein incorporates air-moving mechanism directly on the fin surface and eliminates the external fan or blower, which significantly reduces the size thereof. Possible performance for such an approach can include, for example, dissipating 1000 W heat with less than 33 watt power consumption and 0.05 deg C/watt thermal resistances. It can be appreciated, of course, that such parameters are merely suggestions and not considered limiting features of the disclosed embodiments.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a schematic view of an entrainment heatsink system with engine air bleed, in accordance with a preferred embodiment;

FIG. 2 illustrates a perspective view of an integrated circuit chip, in accordance with a preferred embodiment;

FIG. 3 illustrates a perspective cut view of a part of cooling fins, in accordance with a preferred embodiment;

FIG. 4 illustrates the engine bleed air flow route to the heatsink system, which can be implemented in accordance with an alternative embodiment; and

FIG. 5 illustrates a flow chart illustrating operational steps of a method for a heatsink system, which can be implemented in accordance with the preferred embodiment.

### DETAILED DESCRIPTION

The particular values and configurations discussed in these non-limiting examples can be varied and are cited merely to illustrate at least one embodiment and are not intended to limit the scope thereof.

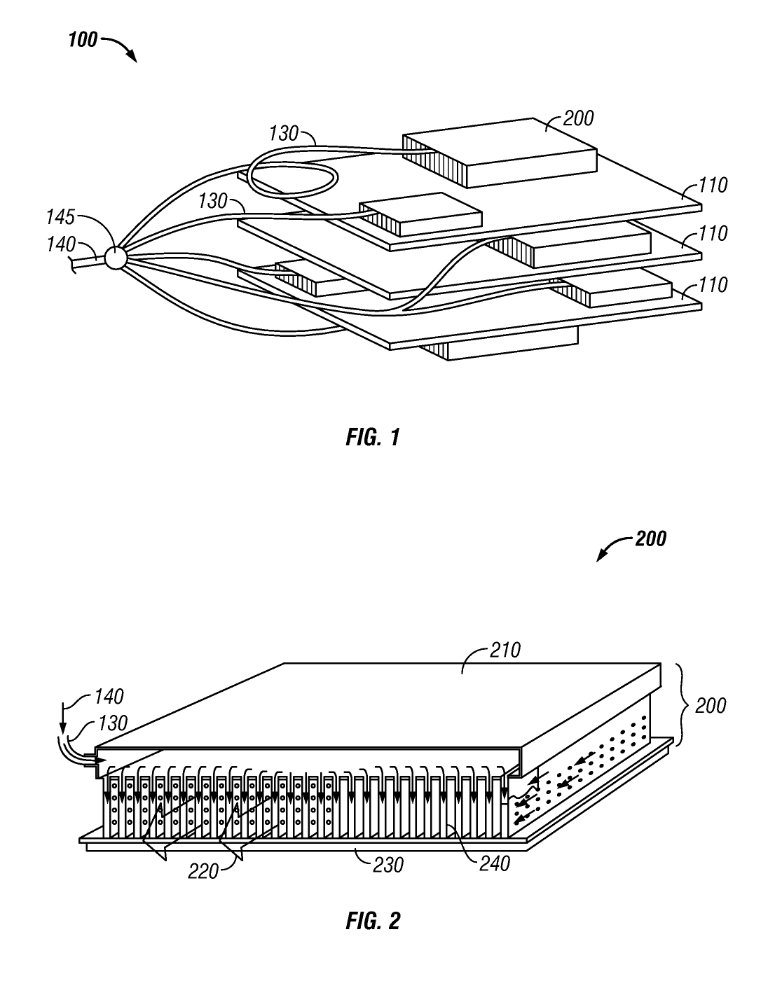

FIG. 1 illustrates a schematic view of an entrainment heatsink system 100 with engine air bleed, in accordance with a preferred embodiment. The entrainment heatsink system 100 generally includes one or a plurality of substrates or printed board assemblies (PBA) 110 upon which one or more heatsinks 200 are mounted in thermal contact with heat generating components (not shown). The bleed air indicated by the arrow 140 can first enter a manifold 145 and then can be distributed and delivered via the thin and flexible air hoses 130 to multiple heatsinks 200. The PBA 110 can be utilized to mechanically support and electrically connect electronic components, such as, for example, one or more heatsinks 200 and associated electronic components (not shown). The small diameter air hoses 130 have the flexibility to reach constraint spaces.

The bleed air 140 entering the manifold 145 can be provided in the form of compressed air originating from an aircraft engine (e.g., a turbo jet engine) 410, as illustrated in FIG. 4. The pre-combustion bleed air 140a can be obtained at various compression stages of the jet engine and since it may be quite hot due to adiabatic compression, it may need to be cooled to be close to the ambient air temperature via a heat exchanger 420. Thereafter, the cooled bleed air 140 can be used for various operations such as air conditioning (A/C) and ventilation. A small fraction of the bleed air 140 can be directed to the manifold 145 as the primary flow source for the entrainment heatsinks 200. Note that an “aircraft engine” as discussed herein typically includes an Auxiliary Power Unit (APU) which includes a small turbine engine utilized to start the main engine and power various electrical systems.

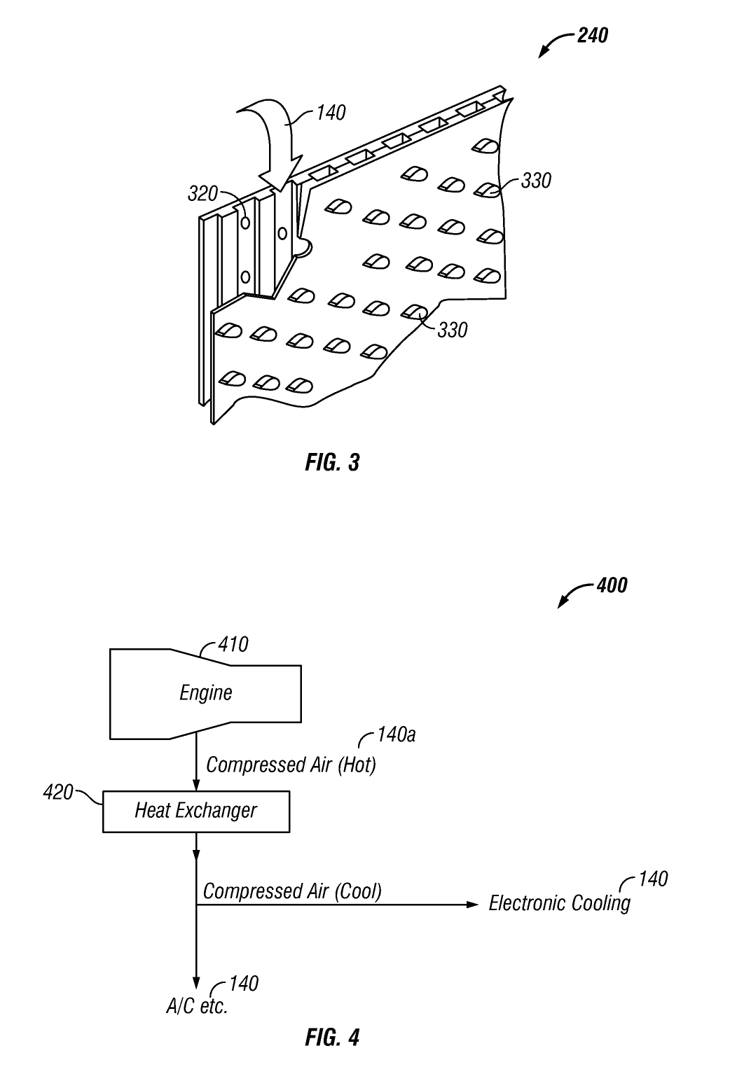

FIG. 2 illustrates a perspective view of an entrainment heatsink 200 which is in thermal contact with a heat generating component 230, such as an IC chip, in accordance with a preferred embodiment. The heatsink is comprised of a manifold 210 and a plurality of fins 240, which further include small air channels 320 and micro nozzles 330, as shown in FIG. 3. The manifold 210 is a sealed volume in fluidic connection with air channels 320 on multiple fins 240. The manifold 210 receives compressed air 140 from air hose 130 and evenly distributes the compressed air 140 to micro nozzles 330 via air channels 320 on multiple fins 240.

As the compressed air exits micro nozzles 330, it attains a jet speed of 100 m/s to 300 m/s depending on the pressure. As the jets interact with the surrounding air, the momentum of the jets is transferred to a much larger amount of air, resulting in the movement of a much larger mass of air at a slower speed (e.g. 1 m/s to 20 m/s), as indicated by arrow 220 in the illustration of FIG. 2. The heat-generating components 230 can be, for example, a CPU (Central Processing Unit) utilized in computers, power amplifiers, RF devices and high-power lasers. The heat generated by 230 flows along fins 240 and is transferred to air stream 220. The larger the mass flow rate of the air stream 220, the better cooling performance can be achieved.

FIG. 3 illustrates a perspective cut view of a part of cooling fins 240, in accordance with a preferred embodiment. The surface of the cooling fins 240 includes a dense array of micro nozzles 330 which are in fluidic connection with air channels 320. The bleed air 140 can be introduced into the air channels 320 and exit from the micro nozzles 330 at high speed thereby creating a micro jet entrainment. The jets are oriented in the direction predominately parallel to the fin surface to maximize the entrainment flow 220. A high degree of turbulence can surround the micro jets, which is beneficial for the enhancement of heat transfer from the fin surface to the air stream 220. The nozzles 330 and air channels 320 can be fabricated using various microfabrication technologies such as silicon-based micromachining, plating, and laser machining.

FIG. 4 illustrates the bleed air flow route from a jet engine 410, which can be implemented in accordance with an alternative embodiment. Note that in FIGS. 1-5, identical or similar parts are generally indicated by identical reference numerals. The compressed air 140a can be obtained from various stages from the compression prior to the combustion. The primary utilization of the compressed air is for air conditioning, ventilation, and other pneumatic operations. As such, the optimal pressure of 140a is determined mainly by these applications, but is generally suitable for the heatsink system 100. As the compressed air 140a is typically hot due to adiabatic compression, it must be cooled to be close to the ambient temperature by a heat exchanger 420. The cooled compressed air 140 can be delivered to various operations including the heatsink system 100. The air flow drawn by the heatsink system 100 is a minute fraction of the total air bleed; it has negligible effect on other operations using the same compressed air source.

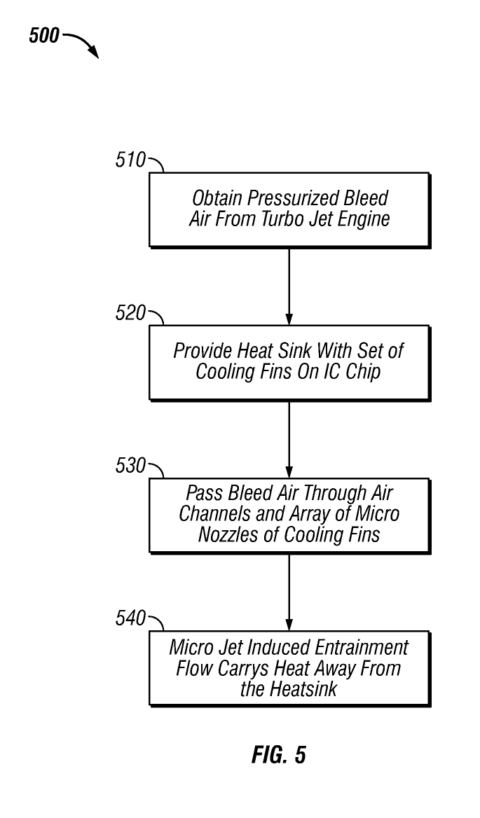

FIG. 5 illustrates a flow chart illustrating operational steps of method 500 for a heatsink system 100, which can be implemented in accordance with the preferred embodiment. As illustrated at block 510, pressurized bleed air can be obtained from the turbo jet engine 410 and cooled by heat exchanger 420. As depicted at block 520, a heatsink 200 with a set of cooling fins 240 can be provided on an IC chip 230.

The set of cooling fins 240 can include a set of air channels 320 in fluidic connection with a dense array of micro nozzles 330. As indicated at block 530, the bleed air can be passed through the air channels 320 and the dense array of micro nozzles 330 of the cooling fins 240 via small diameter hoses 130. Finally, as illustrated at block 540, a pressurized primary flow 140 can be employed to create micro jets through the array of micro nozzles 330, thereby entrain a much larger secondary flow to carry heat away from the heatsink 200 and thereby the heatsink system can significantly enhance heat transfer and cooling performance.

Possible applications for such an approach include thermal management for military and commercial avionics. For example, such an approach can be used to cool chips utilized in an Image Process Module for cockpit displays, power amplifiers, RF transmitters, and high power lasers.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A heatsink apparatus, comprising:
an entrainment heatsink comprising a plurality of cooling fins that are fabricated with an array of micro nozzles and a plurality of air channels, wherein the micro nozzles and the air channels are in fluidic connection; and
a pressurized primary flow employed through said array of micro nozzles to entrain a much larger secondary flow to carry heat away from said entrainment heatsink.

2. The apparatus of claim 1 wherein said pressurized primary flow utilizes bleed air from a pressurized air source for said entrainment heatsink.

3. The apparatus of claim 2 wherein said pressurized air source is associated with an aircraft engine.

4. The apparatus of claim 1 wherein said array of micro nozzles directs said engine bleed air on said plurality of fins utilizing micro-jets entrainment.

5. The apparatus of claim 1 further comprising a plurality of small diameter air hoses for passing said bleed air from said aircraft engine to said plurality of cooling fins.

6. The apparatus of claim 1 wherein said plurality of cooling fins is fabricated with said plurality of micro nozzles utilizing MEMS technology.

7. The apparatus of claim 1 wherein said plurality of cooling fins is fabricated with said plurality of micro nozzles utilizing laser machining.

8. The apparatus of claim 1 further comprising a plurality of small diameter air hoses for passing said bleed air from said aircraft engine to said plurality of cooling fins, wherein said array of micro nozzles directs said engine bleed air on said plurality of fins utilizing micro-jets entrainment, wherein said pressurized primary flow utilizes bleed air from a pressurized air source for said entrainment heatsink and wherein said pressurized air source is associated with an aircraft engine.

9. The apparatus of claim 1 wherein:
said pressurized primary flow utilizes bleed air from a pressurized air source for said entrainment heatsink;
said pressurized air source is associated with an aircraft engine; and
said array of micro nozzles directs said engine bleed air on said plurality of fins utilizing micro-jets entrainment.

10. A heatsink apparatus, comprising:
an entrainment heatsink comprising a plurality of cooling fins that are fabricated with an array of micro nozzles and a plurality of air channels, wherein the micro nozzles and the air channels are in fluidic connection;
a pressurized primary flow employed through said array of micro nozzles to entrain a much larger secondary flow to carry heat away from said entrainment heatsink;
wherein said pressurized primary flow utilizes bleed air from a pressurized air source for said entrainment heatsink; and
wherein said pressurized air source is associated with an aircraft engine.

11. The apparatus of claim 10 wherein said array of micro nozzles directs said engine bleed air on said plurality of fins utilizing micro-jets entrainment.

12. The apparatus of claim 10 further comprising a plurality of small diameter air hoses for passing said bleed air from said aircraft engine to said plurality of cooling fins.

13. The apparatus of claim 10 wherein said plurality of cooling fins is fabricated with said plurality of micro nozzles utilizing MEMS technology.

14. The apparatus of claim 10 wherein said plurality of cooling fins is fabricated with said plurality of micro nozzles utilizing laser machining.

15. The apparatus of claim 10 further comprising a plurality of small diameter air hoses for passing said bleed air from said aircraft engine to said plurality of cooling fins, wherein said array of micro nozzles directs said engine bleed air on said plurality of fins utilizing micro-jets entrainment, and wherein said plurality of cooling fins is fabricated with said plurality of micro nozzles utilizing MEMS technology.

16. The apparatus of claim 10 further comprising a plurality of small diameter air hoses for passing said bleed air from said aircraft engine to said plurality of cooling fins, wherein said array of micro nozzles directs said engine bleed air on said plurality of fins utilizing micro-jets entrainment, and wherein said plurality of cooling fins is fabricated with said plurality of micro nozzles utilizing laser machining.

17. A thermal management system, comprising:
at least one heatsink device among a plurality of heatsink devices, comprising:
an entrainment heatsink comprising a plurality of cooling fins that are fabricated with an array of micro nozzles and a plurality of air channels, wherein the micro nozzles and the air channels are in fluidic connection;
a pressurized primary flow employed through said array of micro nozzles to entrain a much larger secondary flow to carry heat away from said entrainment heatsink;
said plurality of heatsink devices disposed on a plurality of supporting substrates; and
a plurality of small diameter air hoses for passing a pressurized air from a common pressurized air source to said plurality of heatsink devices.

18. The system of claim 17 wherein said pressurized air source is associated with an aircraft engine.

19. The system of claim 17 wherein said plurality of cooling fins is fabricated with said plurality of micro nozzles utilizing MEMS technology.

20. The system of claim 17 wherein said plurality of cooling fins is fabricated with said plurality of micro nozzles utilizing laser machining.
